(19) United States
(12) Patent Application Publication
(10) Pub. No.: US 2008/0123304 A1
(43) Pub. Date: May 29, 2008

(54) Method and/or apparatus for locking circuit packs in a rack

(76) Inventors: Stuart O. Goldman, Scottsdale, AZ (US); Richard E. Krock, Naperville, IL (US); Karl F. Rauscher, Emmaus, PA (US); James Philip Runyon, Wheaton, IL (US)

Correspondence Address: FAY SHARPE/LUCENT, 1100 SUPERIOR AVE, SEVENTH FLOOR, CLEVELAND, OH, 44114, US

(21) Appl. No.: 11/606,215

(22) Filed: Nov. 29, 2006

(51) Int. Cl. H05K 5/00

(52) U.S. Cl. 361/731

(57) ABSTRACT

A piece of telecommunications equipment (A) includes: a plurality of circuit packs (20), each circuit pack (20) including a circuit arranged thereon and a first connector (24) in communication with the circuit; a rack (10) including a plurality of slots (12), each slot (12) including a second connector (14) and being arranged to have at least one of the circuit packs (20) selectively installed therein such that when a circuit pack (20) is installed in a slot (12) the first connector (24) of the circuit pack (20) operatively connects with the second connector (14) of the slot (12); a plurality of locking mechanisms, each of the locking mechanisms being associated with one of the slots (12); and, a controller (40) that selectively engages and disengages the locking mechanisms such that when a locking mechanism is engaged a circuit pack (20) installed in the corresponding slot (12) is secured therein and when a locking mechanism is disengaged a circuit pack (20) installed in the corresponding slot (12) is free to be removed therefrom.

### FIELD

The present inventive subject matter relates to the telecommunication arts. Particular application is found in conjunction with certain types of telecommunication switches, and the specification makes particular reference thereto. However, it is to be appreciated that aspects of the present inventive subject matter are also amenable to other like applications and/or telecommunications equipment.

### BACKGROUND

In general, telecommunications switches and similar or adjunct electronic equipment are known to be employed in telecommunications networks, e.g., such as the Public Switched Telephone Network (PSTN) or the like. Common telecommunications switches include the 5ESS produced by Lucent Technologies and other class five switches or SS7 (Signaling System 7) switches. The network may include hard switches or soft switches or a combination thereof. Telecommunication switches and/or other electronic equipment are typically employed in an end office (EO) or central office (CO) or other telecommunications facilities. Other facilities, e.g., such as a mobile switching center (MSC), employ similar and/or other electronic telecommunications equipment to carry out their functions.

Often, in a given facility, the foregoing telecommunications equipment is implemented as a collection or matrix of separate circuit packs installed in one or more frames or racks. Each pack is commonly an electronic circuit or the like arranged, e.g., on a printed circuit board (PCB) or other platform or base, and generally, each pack has one or more particular functions that are performed or supported thereby. For example, a particular pack may provide or support telephone service to a number of subscribers operatively connected to a telecommunications switch in the usual manner, e.g., via a twisted wire pair.

A typically electronics rack or frame includes one or more shelves or slots or other like partitions into which the packs are selectively installed. Each slot and each corresponding pack is commonly provisioned with mated sockets and plugs or other mated connectors that suitably connect with one another when the pack is properly installed in its corresponding slot. When the packs are connected to the rack or frame in this manner, they are able to communicate with and/or otherwise interact with the other packs in the rack and/or other equipment components operatively connected to the rack.

From time to time, a pack may have to be removed from its rack or frame for maintenance and/or replacement purposes. Of course, when a pack is uninstalled or removed from its slot or otherwise disconnected from the rack or frame, the function or service provided by that pack is lost or disabled. Accordingly, often equipment will be provisioned with redundant packs so that the equipment can remain fully functional during maintenance periods. Of course, non-vital or less important functions may not be supported by redundant packs. Nevertheless, with regard to redundant packs, two packs that provide the identical function or service, for example, may be installed in a rack or frame of a given piece of telecommunications equipment. Generally, one (say for example pack “A”) is live or on-line, while the other (say for example pack “B”) is dormant or off-line. When the time comes for pack A to be repaired, replaced or otherwise serviced, pack B is brought on-line or made live, while pack A is taken off-line or set dormant. Accordingly, pack A can be removed from the rack for servicing without the associated equipment experiencing a loss of functionality, because pack B is now providing the same or equivalent functionality previously provided by pack A. As can be appreciated, however, if an on-line or live pack is removed or disconnected from the rack, while its redundant counterpart is off-line or dormant, then the equipment will undesirably experience a loss of functionality or service.

Typically, a diagnostic system associated with the particular equipment periodically or otherwise runs diagnostic tests on the equipment or packs wherein and identifies which pack or packs a technician or other maintenance individual should remove for servicing. Often, with redundant packs, the packs identified for servicing are taken off-line while their redundant counterparts are placed on-line. However, the technician may inadvertently remove the wrong pack from the rack. That is to say, e.g., a rack typically contains many packs and through human error the technician may inadvertently remove one pack from the rack thinking it to in fact be another pack. In another example, the diagnostic system may identify the pack in row 3, column 2 of the rack as being due for service. However, a technician accidentally transposing the numbers may inadvertently remove the pack in row 2, column 3. Additionally, a pack may be accidentally removed or disconnected from a rack or frame, e.g., it may be pulled out or disconnected upon being snagged on the clothing of a passerby.

As can be appreciated, if a pack which is inadvertently, accidentally or otherwise removed or disconnected from the rack is live or on-line, then the equipment will undesirably experience a loss of functionality. As a result, for example, one or more subscribers may lose telephone service. It is desirable, therefore, to have a way to guard against the inadvertent, accidental, mistaken or otherwise unwanted removal or disconnection of circuit packs from their racks or frames.

Accordingly, a new and improved method and/or apparatus for locking circuit packs in a rack is disclosed that overcomes the above-referenced problems and others.

### SUMMARY

In accordance with one embodiment, a piece of telecommunications equipment is provided. The equipment includes: a plurality of circuit packs, each circuit pack including a circuit arranged thereon and a first connector in communication with the circuit; a rack including a plurality of slots, each slot including a second connector and being arranged to have at least one of the circuit packs selectively installed therein such that when a circuit pack is installed in a slot the first connector of the circuit pack operatively connects with the second connector of the slot; a plurality of locking mechanisms, each of the locking mechanisms being associated with one of the slots; and, a controller that selectively engages and disengages the locking mechanisms such that when a locking mechanism is engaged a circuit pack installed in the corresponding slot is secured therein and when a locking mechanism is disengaged a circuit pack installed in the corresponding slot is free to be removed therefrom.

In accordance with another embodiment, a method is provided for selectively locking a circuit pack in a slot of a rack. The method includes: (a) installing the circuit pack in the slot of the rack; (b) determining if the circuit pack is to be locked in the slot of the rack; and, (c) responsive to step (b), selectively operating a locking mechanism such that when the locking mechanism is engaged the circuit pack is locked in the slot and when the locking mechanism is disengaged the circuit pack is free to be removed from the slot.

In accordance with yet another embodiment, a.

Numerous advantages and benefits of the inventive subject matter disclosed herein will become apparent to those of ordinary skill in the art upon reading and understanding the present specification.

### BRIEF DESCRIPTION OF THE DRAWINGS

The inventive subject matter may take form in various components and arrangements of components, and in various steps and arrangements of steps. The drawings are only for purposes of illustrating preferred embodiments and are not to be construed as limiting. Further, it is to be appreciated that the drawings are not to scale.

FIG. 1 is a diagram illustrating a front view of an exemplary piece of telecommunications equipment suitable for practicing aspects of the present inventive subject matter.

FIG. 2 is a diagram illustrating a side view of an exemplary circuit pack suitable for practicing aspects of the present inventive subject matter.

FIG. 3 is a diagram illustrating a top cross-section view of the circuit pack of FIG. 2 installed in a slot of the rack from FIG. 1, with the circuit pack being locked in the rack.

FIG. 4 is a diagram illustrating the same view as FIG. 3, with the circuit pack being unlocked from the rack.

### DETAILED DESCRIPTION OF PREFERRED EMBODIMENTS

For clarity and simplicity, the present specification shall refer to structural and/or functional elements, entities and/or facilities, relevant communication standards, protocols and/or services, and other components that are commonly known in the telecommunications art without further detailed explanation as to their configuration or operation except to the extent they have been modified or altered in accordance with and/or to accommodate the preferred embodiment(s) presented herein.

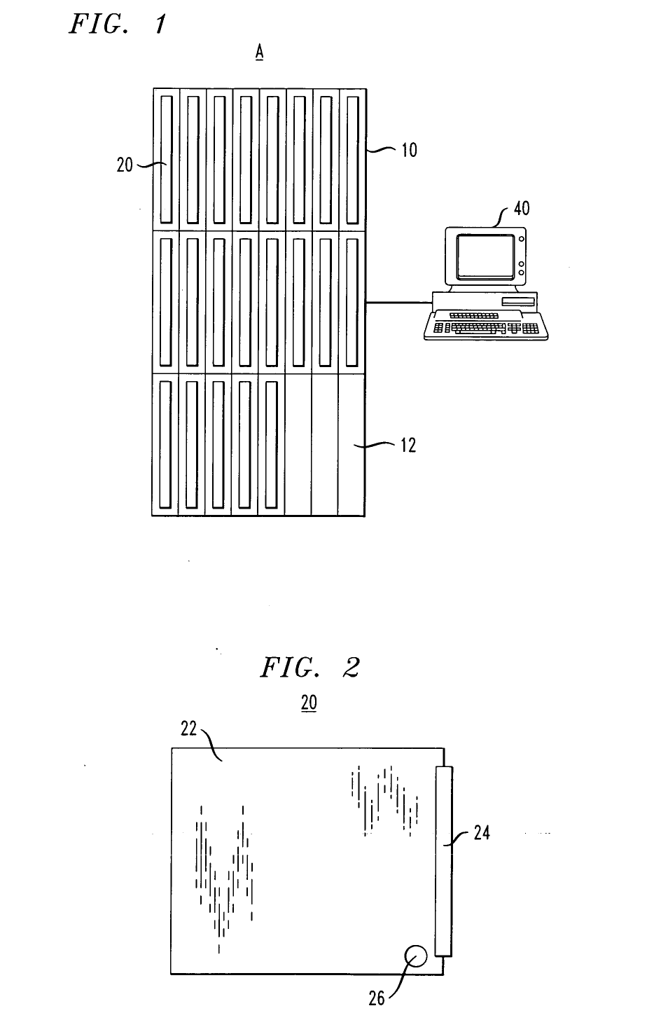

With reference to FIG. 1, there is shown a piece of telecommunications equipment A, e.g., a telecommunications switch. As shown, the equipment A includes a frame or rack 10 having a plurality of shelves, partitions and/or slots 12 in which circuit packs 20 are selectively installed. Suitably, each slot 12 is dimensioned and/or arranged to receive and/or hold a single pack 20. As shown, the equipment A is implemented as a single rack 10 that includes 24 slots 12, 21 of which have installed therein respective circuit packs 20. For illustrative purposes, 3 slots 12 are shown empty. However, it is to be appreciated, that the equipment A is optionally implemented with a plurality of racks having more or less slots holding more or less circuit packs. That is to say, the number of racks, slots and circuit packs representing the equipment shown in the present drawing is for illustrative purposes only.

With reference to FIG. 2, suitably, each pack 20 is an electronic circuit or the like arranged, e.g., on a PCB 22 or other platform or base, and each pack 20 provides or supports one or more particular functions or services for the equipment A. For example, a particular pack 20 may provide or support telephone service to a number of subscribers operatively connected to a telecommunications switch in the usual manner, e.g., via a twisted wire pair.

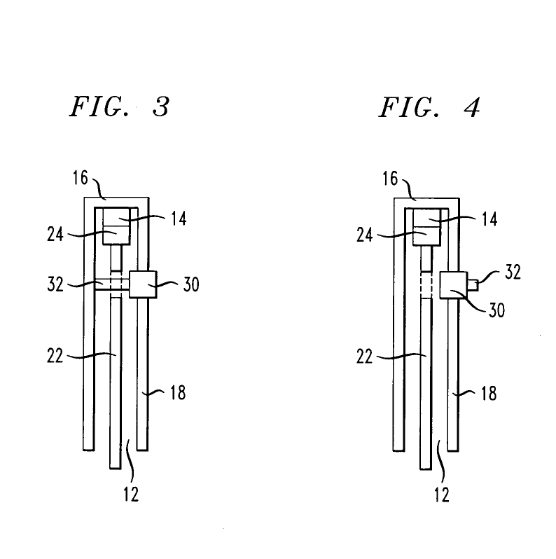

With reference to FIGS. 3 and 4, suitably, each slot 12 and each corresponding pack 20 is provisioned with one part of a mated socket and plug pair or other mated connectors 14 and 24 that suitably connect with one another when the pack 20 is properly installed in its corresponding slot 12. When the packs 20 are connected to the frame or rack 10 in this manner, the packs 20 are able to communicate with and/or otherwise interact with the other packs 20 in the rack 10 and/or other equipment components operatively connected to and/or in communication with the rack 10. Conversely, when a pack 20 is uninstalled or removed from its slot 12 or otherwise disconnected from the rack 10, the function or service provided by that pack 20 is lost or disabled.

Suitably, a back wall or back plane 16 of the rack 10 has attached thereto or affixed thereon an array or matrix of the connectors 14 arranged or otherwise positioned so that they line-up or coincide with the array or matrix of slots 12 in the rack 10. Accordingly, when a pack 20 is inserted or otherwise installed in its respective slot 12, the connector 24 arranged on the pack 20 joins or otherwise operatively connects with the connector 14 in the back of the slot 12. In this way, the circuit pack 20 is operatively connected to the rack 10, and the circuit on the circuit pack 20 is made part of the equipment A. That is to say, the function or service provided or supported by the installed or otherwise connected pack 20 is enabled on the equipment A.

To uninstall a pack 20 or disconnect a pack 20 from the rack 10, the pack 20 is simply pulled or otherwise removed from its respective slot 12, thereby separating or otherwise breaking the connection between the connectors 24 and 14. Generally, however, under normal operating conditions, the packs 20 are locked or otherwise secured in their respective slots 12 to guard against unintentional, accidental, mistaken or otherwise undesired removal or disconnection of the packs 20. Suitably, each slot 12 is provisioned with a locking mechanism that can be selectively engaged to secure the respective pack 20 in the slot 12, or selectively disengaged to free the pack 20 for removal from the slot 12 and/or disconnection from the rack 10.

As shown in FIGS. 3 and 4, the locking mechanism is attached or secured to or otherwise arranged on the rack 10, e.g., on a partition wall or side wall 18. Accordingly, the locking mechanism is fixed with respect to the rack 10, and in turn, such circuit packs 20 as are locked or otherwise held by the locking mechanism are also secured in place relative to the rack 10. In the illustrated embodiment, the locking mechanism includes an actuator 30 and a movable rod, shaft, bolt or other locking member 32. Suitably, the actuator 30 regulates the movement of the locking member 32 in response to a control signal received by the actuator 30. For example, as shown in FIG. 3, when the locking mechanism is engaged, the actuator 30 extends the locking member 32 through the hole or opening 26 (see FIG. 2 also) formed in the PCB 22 of the pack 20, thereby creating a physical barrier and/or mechanical interference that blocks or inhibits removal of the pack 20 from the slot 12 so that the pack 20 remains securely connected to the rack 10. Conversely, for example, as shown in FIG. 4, when the locking mechanism is disengaged, the actuator 30 retracts the locking member 32 from the hole or opening 26 (see FIG. 2 also) formed in the PCB 22 of the pack 20, thereby freeing the pack 20 for removal from the slot 12 and/or disconnection from the rack 10.

Suitably, the actuator 30 is an electromechanical device that produces a desired movement in response to appropriate electrical energizing of the actuator 30. In one suitable embodiment, the actuator 30 is optionally a solenoid or other like device that produces the movement of the locking member 32 in response to a control signal received by the actuator 30. Optionally, the locking member 32 is biased (e.g., by a spring or otherwise) into the disengaged position (e.g., as shown in FIG. 4), and energizing of the actuator 30 causes the actuator 30 to move the locking member 32 into the engaged position (e.g., as shown in FIG. 3). Accordingly, should there be a loss of power, the locking mechanisms will be biased toward,.their disengaged states allowing the packs 20 to be selectively removed from their slots 12 and/or disconnected from the rack 10.

While the operation of the locking mechanism illustrated in FIGS. 3 and 4 involves the locking member 32 selectively being extended through or removed from the opening 26 as the case may be to engage or disengage the locking mechanism, still other types of locking mechanisms and/or locking operations are optionally employed. For example, the locking mechanism is optionally implemented as a clamp or set of pincers that are selectively actuated to grab and/or hold a particular region or area or location on the circuit pack 20. In another example, the locking mechanism is optionally implemented as a movable latch or hook or other like contrivance that is actuated to selectively attach to or otherwise engage with the circuit pack 20 and hold or otherwise secure the pack 20 in its respective slot 12. In another example, rather than extending entirely through the pack 20, the locking member 32 may merely fit into a corresponding recess dimensioned and/or arranged on the pack 20 to selectively receive the locking member 32. In another example, the selectively actuated portion of the locking mechanism is optionally arranged on the circuit pack 20 and the rack 10 is configured to be selectively engaged thereby. In any event, when the locking mechanism is engaged, the pack 20 is secured in its respective slot 12, and when the locking mechanism is disengaged, the pack 20 is free to be removed from its respective slot 12 or otherwise disconnected from the rack 10.

With reference again to FIG. 1, suitably, a diagnostic and/or circuit pack locking control system (DCS) is associated with the equipment A. For example, this system includes a workstation, terminal or other computer 40 operatively connected to and/or in communication with the rack 10. The computer 40 suitably includes the usual components, user interface and input/output devices, e.g., a monitor or video screen, a mouse and/or other pointing devices, a graphical user interface (GUI), a keyboard, memory, a central processing unit (CPU), a hard disk drive and/or other data storage devices, etc. Optionally, the DCS intermittently or as otherwise directed runs diagnostic tests on the equipment A and/or the packs 20 in the rack 10 and identifies which one or more packs 20 are due for servicing, i.e., which one or more packs 20 a technician or other maintenance individual should remove from their slots 12 and/or disconnect from the rack 10. Suitably, the DCS regulates the locking mechanisms to disengage only those locking mechanisms corresponding to the one or more packs 20 identified as being due for service, while the locking mechanisms corresponding to the rest of the packs 20 in the rack 10 remain engaged. Accordingly, the equipment A is protected against unintentional, accidental or otherwise mistaken removal of the wrong pack 20. Optionally, the technician may employ a user interface on the computer 40 to override any default regulation of the locking mechanisms, e.g., to lock or unlock any one or more particularly specified packs 20 and/or slots 12 or optionally to lock or unlock all of them as desired.

For example, during otherwise normal operating conditions, the computer 40 optionally sends a control signal to the actuators 30 which directs the actuators 30 to move the locking members 32 into the engaged position (as shown in FIG. 3) for all the slots 12 in the rack 10, or at least for those slots 12 having live or on-line circuit packs 20 installed therein. At or about the time a diagnostic text is completed by the DCS, the computer 40 optionally sends a control signal to the actuators 30 which directs the actuators 30 to move the locking members 32 into the disengaged position (as shown in FIG. 4) for all the slots 12 in the rack 10 having installed therein a pack 20 that has been identified as due for servicing. Suitably, the DCS also takes the circuit packs 20 identified for servicing off-line or otherwise sets them dormant. Accordingly, those circuit packs 20 identified as being due for servicing are free to be removed from their respective slots 12 by the attending technician. However, if the technician should attempt to pull or otherwise remove another one of the packs 20 from its slot 12 (i.e., a pack 20 which has not been unlock), then the technician will encounter significant resistance to the attempted removal insomuch as the corresponding locking mechanism is still engaged. This will in turn indicate to the technician that they are attempting to remove the wrong circuit pack 20. Nevertheless, if the technician still desires to remove the pack 20 at issue, they may employ the aforementioned override procedure to unlock the pack 20 from its corresponding slot 12 in the rack 10.

Notwithstanding the foregoing examples, it is to be appreciated that the locking mechanisms are optionally controlled and/or regulated in any suitable manner as may be deemed appropriate for a given circumstance or a particular application. That is to say, the default state of any one or more of the locking mechanisms may be engaged or disengaged, e.g., depending upon the nature of the circuit pack 20 installed in the particular slot 12. Moreover, the changing of a particular lock from the engaged state to the disengaged state or vice versa may also be automatically executed based upon any one or more detected conditions or executed at the direction of an individual, e.g., operating the computer 40. For example, suitably, the DCS detects which packs 20 are on-line or live and/or which packs 20 are off-line or dormant, and accordingly, the default state output by the DCS (i.e., the default control signals sent to the respective actuators 30) is such that the packs 20 which are on on-line or live optionally have their corresponding locking mechanisms engaged, while packs 20 that are off-line or dormant optionally have their corresponding locking mechanisms disengaged. Of course, as a pack 20 switches from an on-line or live state to an off-line or dormant state and vise versa, the control signal sent to the actuator 30 of the corresponding locking mechanism is likewise altered accordingly to effectuate the locking or unlocking of the pack 20 as is appropriate for the particular case.

It is to be appreciated that in connection with the particular exemplary embodiments presented herein certain structural and/or function features are described as being incorporated in defined elements and/or components. However, it is contemplated that these features may, to the same or similar benefit, also likewise be incorporated in other elements and/or components where appropriate. It is also to be appreciated that different aspects of the exemplary embodiments may be selectively employed as appropriate to achieve other alternate embodiments suited for desired applications, the other alternate embodiments thereby realizing the respective advantages of the aspects incorporated therein.

It is also to be appreciated that particular elements or components described herein may have their functionality suitably implemented via hardware, software, firmware or a combination thereof. Additionally, it is to be appreciated that certain elements described herein as incorporated together may under suitable circumstances be stand-alone elements or otherwise divided. Similarly, a plurality of particular functions described as being carried out by one particular element may be carried out by a plurality of distinct elements acting independently to carry out individual functions, or certain individual functions may be split-up and carried out by a plurality of distinct elements acting in concert. Alternately, some elements or components otherwise described and/or shown herein as distinct from one another may be physically or functionally combined where appropriate.

In short, the present specification has been set forth with reference to preferred embodiments. Obviously, modifications and alterations will occur to others upon reading and understanding the present specification. It is intended that the invention be construed as including all such modifications and alterations insofar as they come within the scope of the appended claims or the equivalents thereof.

What is claimed is:

1. A piece of telecommunications equipment, said equipment comprising:
a plurality of circuit packs, each circuit pack including a circuit arranged thereon and a first connector in communication with said circuit;
a rack including a plurality of slots, each slot including a second connector and being arranged to have at least one of the circuit packs selectively installed therein such that when a circuit pack is installed in a slot the first connector of the circuit pack operatively connects with the second connector of the slot;
a plurality of locking mechanisms, each of said locking mechanisms being associated with one of said slots; and,
a controller that selectively engages and disengages said locking mechanisms such that when a locking mechanism is engaged a circuit pack installed in the corresponding slot is secured therein and when a locking mechanism is disengaged a circuit pack installed in the corresponding slot is free to be removed therefrom.

2. The equipment of claim 1, wherein each locking mechanism includes:
an actuator that is operative to selectively engage and disengage the locking mechanism in response to a control signal from the controller.

3. The equipment of claim 2, wherein each locking mechanism includes:
a movable locking member that is moved by the actuator between a first position in which the locking mechanism is engaged and a second position in which the locking mechanism is disengaged.

4. The equipment of claim 3, wherein each circuit pack has an opening formed therein such that when a circuit pack is installed in a slot and the locking member of the corresponding locking mechanism for that slot is in the first position, the locking member extends through the opening of the installed circuit pack.

5. The equipment of claim 4, wherein when a circuit pack is installed in a slot and the locking member of the corresponding locking mechanism for that slot is in the second position, the locking member is retracted out of the opening of the installed circuit pack.

6. The equipment of claim 3, wherein the actuator of at least one of the locking mechanisms is a solenoid.

7. The equipment of claim 1, wherein at least one of the locking mechanisms is secured to the rack.

8. The equipment of claim 2, wherein the controller is operative to run a diagnostic test on at least one of the circuit packs installed in a slot of the rack, and the controller sends a control signal to the actuator of the corresponding locking mechanism associated with the respective slot to selectively engage or disengage the locking mechanism in response to a result of the diagnostic test.

9. The equipment of claim 1, wherein the equipment is a telecommunications switch.

10. A method of selectively locking a circuit pack in a slot of a rack, said method comprising:
(a) installing the circuit pack in the slot of the rack;
(b) determining if the circuit pack is to be locked in the slot of the rack; and,
(c) responsive to step (b), selectively operating a locking mechanism such that when the locking mechanism is engaged the circuit pack is locked in the slot and when the locking mechanism is disengaged the circuit pack is free to be removed from the slot.

11. The method of claim 10, wherein said operating includes sending a control signal to an actuator operative to engage or disengage the locking mechanism in response to the control signal.

12. The method of claim 11, wherein said actuator moves a locking member between a first position in which the locking mechanism is engaged and a second position in which the locking mechanism is disengaged.

13. The method of claim 10, wherein when the locking mechanism is engaged a portion of the locking mechanism extends through an opening in the circuit pack.

14. The method of claim 13, wherein when the locking mechanism is disengaged the portion of the locking mechanism is retracted from the opening in the circuit pack.

15. The method of claim 11, wherein the actuator is a solenoid.

16. The method of claim 10, wherein step (b) comprises:
running a diagnostic test on the circuit pack to determine if the circuit pack is due for servicing.

17. The method of claim 16, wherein the locking mechanism is disengaged if it is determined that the circuit pack is due for servicing, otherwise the locking mechanism is engaged.

18. The method of claim 10, wherein step (b) comprises:
detecting if the circuit pack live or dormant.

19. The method of claim 16, wherein the locking mechanism is disengaged if the circuit pack is dormant and the locking mechanism is engaged if the circuit pack is live.
